(19) United States
(12) Patent Application Publication
(10) Pub. No.: US 2002/0033501 A1
(43) Pub. Date: Mar. 21, 2002

(54) Nonvolatile semiconductor memory and method of fabricating the same

(75) Inventor: Eiji Sakagami, Yokkaichi-Shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Minato-Ku (JP)

(21) Appl. No.: 09/955,076

(22) Filed: Sep. 19, 2001

(30) Foreign Application Priority Data
Sep. 21, 2000 (JP) 2000-287084

(51) Int. Cl. H01L 29/788

(52) U.S. Cl. 257/315

(57) ABSTRACT

A charge storage layer (112) in a gate insulating film of a cell transistor is so formed as not to extend from a channel region of a cell to an element isolation region. Since no electric charge moves from the charge storage layer (112) on the channel onto the element isolation region, the charge retention characteristics improves. Unlike a gate insulating film of a cell transistor, a gate insulating film of a selection transistor is formed without including the charge storage layer (112). This stabilizes read operation because the threshold value of the transistor does not vary. Of peripheral transistors, a thick gate oxide film is formed for a transistor requiring a high-breakdown-voltage gate oxide film, and a thin gate oxide film is formed for a transistor requiring high drivability. This realizes a high operating speed.

### CROSS REFERENCE TO RELATED APPLICATION

This application claims benefit of priority under 35 USC 119 to Japanese Patent Application No. 2000-287084, filed on Sep. 21, 2000, the entire contents of which are incorporated by reference herein.

### BACKGROUND OF THE INVENTION

The present invention relates to a nonvolatile semiconductor memory and a method of fabricating the same and, more particularly, to a memory cell having a MONOS (Metal-Oxide-Nitride-Oxide-Si) structure using SA-STI (Self-Aligned Shallow Trench Isolation) as an element isolation method.

Recently, a cell having a MONOS structure has been proposed as a memory cell of an electrically programmable and erasable nonvolatile semiconductor memory (flash EEPROM).

FIG. 14 shows a longitudinal section near the gate electrode of a memory cell having a MONOS structure related to the present invention. FIG. 15 shows a longitudinal section near a channel region.

An n-type well 8 is formed in a surface region of a p-type semiconductor substrate 9, and a p-type well 1 is formed on top of this n-type well 8. In a surface region of this p-type well 1, a drain region (n-type impurity region) 2, a channel region 11, and a source region (n-type impurity region) 3 are formed. In addition, on the channel region 11, a bottom silicon oxide film 4, an SiN film 5 serving as a charge storage layer, a top silicon oxide film 6, and a control gate electrode 7 are stacked in this order. Channel regions 11 of adjacent cells are electrically isolated by an element isolation region 10.

In the MONOS memory cell having this arrangement, electric charge is injected into the SiN film 5 as a gate insulating film and trapped in the charge capturing center of the film, or the trapped charge is extracted from the SiN film. In this way, the threshold value of the cell is controlled to give it a memory function.

In a nonvolatile memory having this MONOS memory cell, program, erase, and read are performed as follows (“program” is to inject electrons into the SiN film, and “erase” is to extract electrons from the SiN film).

In the program method, as shown in FIG. 16, a program potential (+Vpg) is applied to the control gate electrode 7, and the well region 1, the source region 3, and the drain region 2 are grounded. A high electric field is applied to the SiN film 5 to inject electrons into the SiN film 5 by FN (Fowler-Nordheim) injection.

In the erase method, as shown in FIG. 17, a negative erase potential (−Veg) is applied to the control gate electrode 7, a positive potential (+Vew) is applied to the well 1, and a high electric field is applied to the SiN film 5, thereby tunneling electrons in the SiN film 5 to the semiconductor substrate 9 by FN tunneling.

Unfortunately, the following first, second, and third problems arise when this MONOS memory cell related to the present invention is applied to a nonvolatile semiconductor memory.

First, when a gate insulating film is to be formed in a conventional memory cell, the bottom silicon oxide film 4, the SiN film 5, and the top silicon oxide film 6 are formed after the element isolation regions 10 are formed.

As shown in FIG. 18, therefore, the SiN film 5 as a charge storage layer is formed not only on the channel region 11 but also on the element isolation regions 10. When the charge storage layer is thus formed across the channel region and the element isolation regions, electric charge injected into the charge storage layer on the channel region by program operation is diffused in the charge storage layer by a self-electric field and a thermal excitation phenomenon. Consequently, the charge moves from the channel region to the element isolation regions.

This charge movement reduces the charge amount on the channel and deteriorates the charge retention characteristics of the cell. To prevent the occurrence of this phenomenon, as shown in FIG. 19, isolation regions 12 can be formed on the element isolation regions 10 to isolate the SiN film 5 as a charge storage layer.

Even when this method is used, however, the SiN film 5 is not limited on the channel region 11, i.e., portions 13 extending to the element isolation regions 10 exist. Hence, the charge retention characteristics cannot be well improved.

Also, when a matrix cell array having word and bit lines is fabricated by MONOS cells which perform data program and erase by FN tunneling, selection transistors are necessary to prevent program errors.

In a NOR cell array, as shown in FIG. 20, one memory cell transistor MT and two selection transistors ST1 and ST2 are necessary for each memory cell MC1.

In a NAND cell array, as shown in FIG. 21, series-connected memory cell transistors MT11 to MT1n (n is an integer of 1 or more) and two selection transistors ST11 and ST12 are necessary for each memory cell MC11.

Of these two cell arrays, the NAND cell array is advantageous for microfabrication since the number of selection transistors with respect to memory cell transistors is smaller than in the NOR cell array.

The following second problem exists in the formation of a gate insulating film of a selection transistor.

Memory cells and selection transistors are formed adjacent to each other in a cell array. Conventionally, a memory cell and a selection transistor are given the same configuration without forming any separated gate insulating films. Hence, a gate insulating film of a selection transistor includes a charge storage layer as in a memory cell. Since this varies the threshold value of the selection transistor, read operation of the memory cell becomes unstable.

Third, transistors arranged in a peripheral region of a cell array include those required to have a high breakdown voltage and those required to have not a high breakdown voltage but high drivability. Since the same gate insulating film is conventionally used for these peripheral transistors, a thick insulating film is formed to meet the requirement of the transistor which must have a high breakdown voltage. As a consequence, the drivability of the transistor required to operate at high speed cannot be raised by lowering the threshold value. This leads to a lowering of the operating speed.

Accordingly, demands have arisen for a nonvolatile semiconductor memory which can improve the charge retention characteristics, which can stabilize read operation using a selection transistor, and which can increase the operating speed of a peripheral transistor.

### SUMMARY OF THE INVENTION

According to an aspect of the present invention, a nonvolatile semiconductor memory comprising a semiconductor substrate, a first transistor formed on a surface of the semiconductor substrate and including a first gate insulating film and a first gate electrode, and a second transistor formed on the surface of the semiconductor substrate and including a second gate insulating film and a second gate electrode, wherein the first gate insulating film includes a charge storage layer and the second gate insulating film does not include a charge storage layer, and the first and second transistors are isolated by a trench and the charge storage layer in the first transistor does not exist in an element isolation region and exists only below said first gate electrode in an element region is provided.

According to an aspect of the present invention, a method of fabricating a nonvolatile semiconductor memory having a cell array including a cell transistor and a selection transistor, comprising the steps of forming a first gate insulating film including a charge storage layer, on a surface of a semiconductor substrate, as a gate insulating film of the cell transistor, forming a second gate insulating film not including a charge storage layer, on the surface of the semiconductor substrate, as a gate insulating film of the selection transistor, and performing element isolation by forming a trench between an element region in which the cell transistor is to be formed and an element region in which the selection transistor is to be formed, wherein the charge storage layer in the cell transistor does not exist in an element isolation region and exists only below said first gate electrode in the element region is provided.

A fabrication method of an aspect of the present invention is a method of fabricating a device having a cell array including a cell transistor and a selection transistor, and a peripheral circuit including a peripheral transistor, comprising the steps of forming a first gate insulating film including a charge storage layer, on a surface of a semiconductor substrate, as a gate insulating film of the cell transistor, forming a second gate insulating film not including a charge storage layer, on the surface of the semiconductor substrate, as a gate insulating film of the selection transistor, forming a third gate insulating film not including a charge storage layer, on the surface of the semiconductor substrate, as a gate insulating film of the peripheral transistor, and performing element isolation by forming trenches between an element region in which the cell transistor is to be formed, an element region in which the selection transistor is to be formed, and an element region in which the peripheral transistor is to be formed, wherein the step of forming the second gate insulating film and the step of forming the third gate insulating film are simultaneously performed, and the charge storage layer in the cell transistor does not exist in an element isolation region and exists only below said first gate electrode in the element region.

A fabrication method of an aspect of the present invention is a method of fabricating a device having a cell array including a cell transistor and a selection transistor, and a peripheral circuit including first and second peripheral transistors, comprising the steps of forming a first gate insulating film including a charge storage layer, on a surface of a semiconductor substrate, as a gate insulating film of the cell transistor, forming a second gate insulating film not including a charge storage layer, on the surface of the semiconductor substrate, as a gate insulating film of the selection transistor, forming a third gate insulating film not including a charge storage layer, on the surface of the semiconductor substrate, as a gate insulating film of the first peripheral transistor, forming a fourth gate insulating film not including a charge storage layer and thinner than the third gate insulating film, on the surface of the semiconductor substrate, as a gate insulating film of the second peripheral transistor, and performing element isolation by forming trenches between an element region in which the cell transistor is to be formed, an element region in which the selection transistor is to be formed, and an element region in which the first and second peripheral transistors are to be formed, wherein the step of forming the second gate insulating film and the step of forming the third gate insulating film are simultaneously performed, and the charge storage layer in the cell transistor does not exist in an element isolation region and exists only below said first gate electrode in the element region.

### BRIEF DESCRIPTION OF THE DRAWINGS

FIG. 1 is a longitudinal sectional view showing the section of an element in one step of a method of fabricating a nonvolatile semiconductor memory according to an embodiment of the present invention;

FIG. 2 is a longitudinal sectional view showing the section of the element in one step of the method of fabricating a nonvolatile semiconductor memory according to the same embodiment;

FIG. 3 is a longitudinal sectional view showing the section of the element in one step of the method of fabricating a nonvolatile semiconductor memory according to the same embodiment;

FIG. 4 is a longitudinal sectional view showing the section of the element in one step of the method of fabricating a nonvolatile semiconductor memory according to the same embodiment;

FIG. 5 is a longitudinal sectional view showing the section of the element in one step of the method of fabricating a nonvolatile semiconductor memory according to the same embodiment;

FIG. 6 is a longitudinal sectional view showing the section of the element in one step of the method of fabricating a nonvolatile semiconductor memory according to the same embodiment;

FIG. 7 is a longitudinal sectional view showing the section of the element in one step of the method of fabricating a nonvolatile semiconductor memory according to the same embodiment;

FIG. 8 is a longitudinal sectional view showing the section of the element in one step of the method of fabricating a nonvolatile semiconductor memory according to the same embodiment;

FIG. 9 is a longitudinal sectional view showing the section of the element in one step of the method of fabricating a nonvolatile semiconductor memory according to the same embodiment;

FIG. 10 is a longitudinal sectional view showing the section of the element in one step of the method of fabricating a nonvolatile semiconductor memory according to the same embodiment;

FIG. 11 is a longitudinal sectional view showing the section of the element in one step of the method of fabricating a nonvolatile semiconductor memory according to the same embodiment;

FIG. 12 is a longitudinal sectional view showing the section of the element in one step of the method of fabricating a nonvolatile semiconductor memory according to the same embodiment;

FIG. 13 is a longitudinal sectional view showing the section of the element in one step of the method of fabricating a nonvolatile semiconductor memory according to the same embodiment, and also showing the structure of the memory;

FIG. 14 is a longitudinal sectional view showing an arrangement near a gate electrode in a nonvolatile semiconductor memory related to the present invention;

FIG. 15 is a longitudinal sectional view showing the arrangement of element isolation regions in the same nonvolatile semiconductor memory;

FIG. 16 is a view for explaining program operation in the same nonvolatile semiconductor memory;

FIG. 17 is a view for explaining erase operation in the same nonvolatile semiconductor memory;

FIG. 18 is a view for explaining a mechanism of deteriorating the charge retention characteristics in the same nonvolatile semiconductor memory;

FIG. 19 is a longitudinal sectional view showing the structure of a nonvolatile semiconductor memory related to the present invention, in which the charge retention characteristics is improved;

FIG. 20 is a circuit diagram showing the arrangement of a NOR array in a MONOS cell; and

FIG. 21 is a circuit diagram showing the arrangement of a NAND array in a MONOS cell.

### DESCRIPTION OF THE PREFERRED EMBODIMENT

An embodiment of the present invention will be described below with reference to the accompanying drawings.

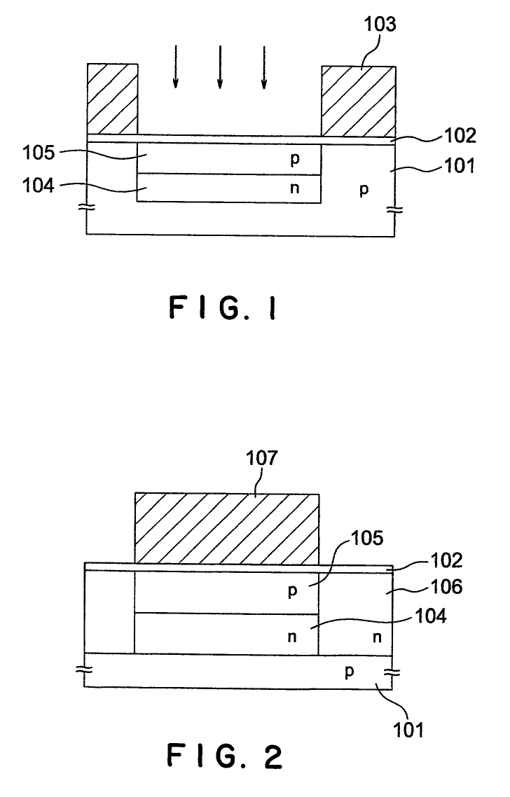

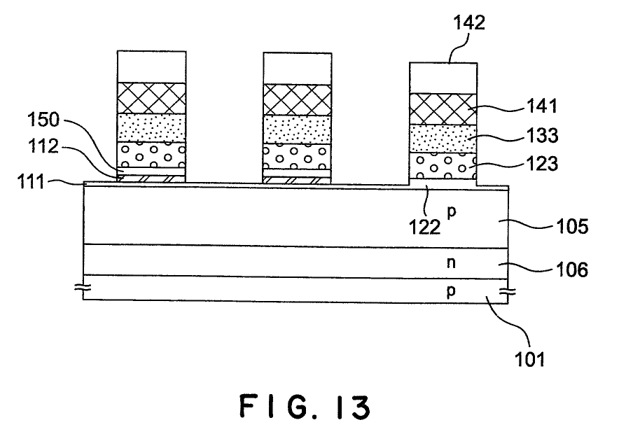

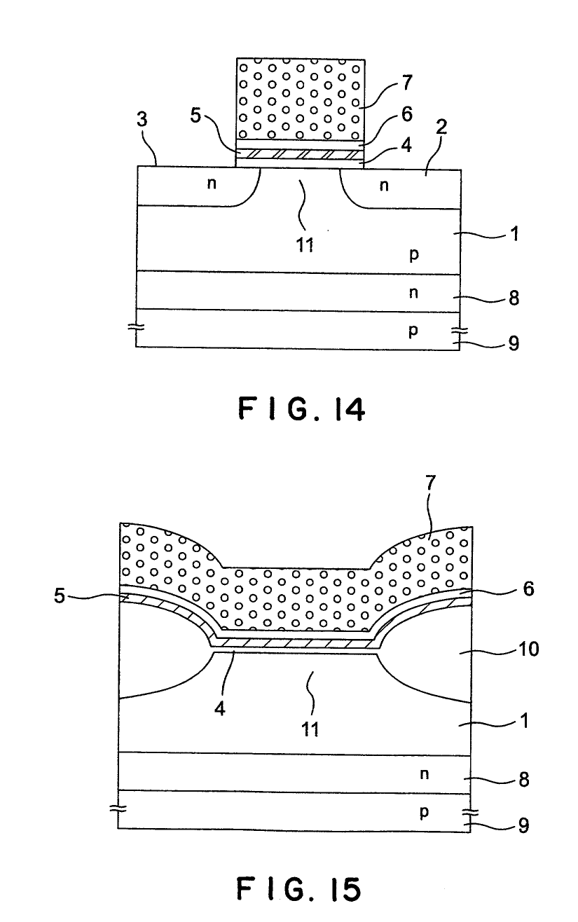

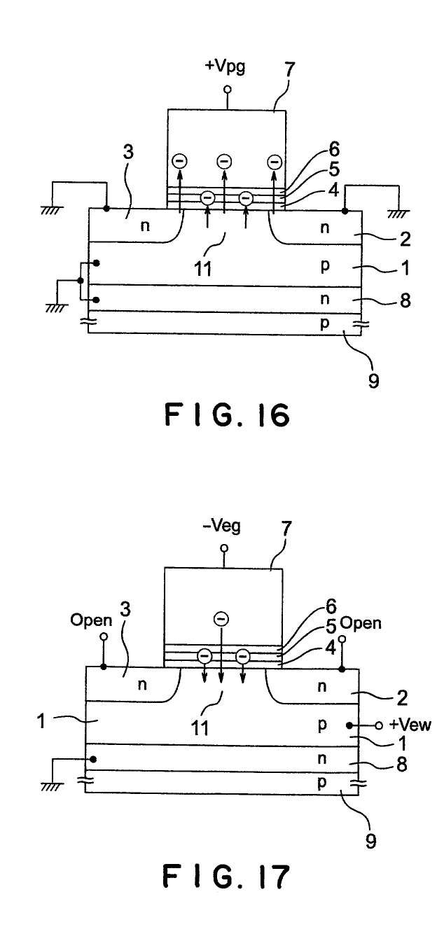

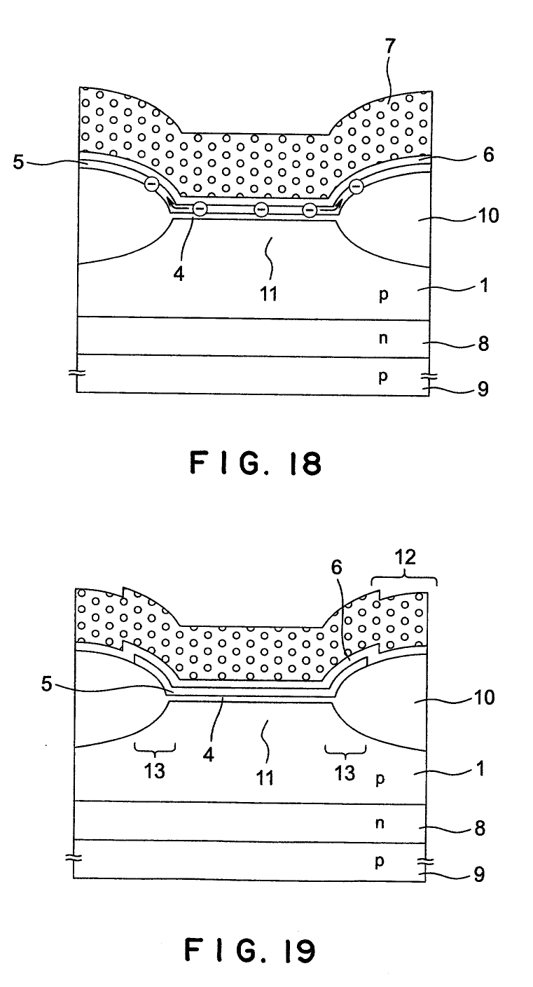

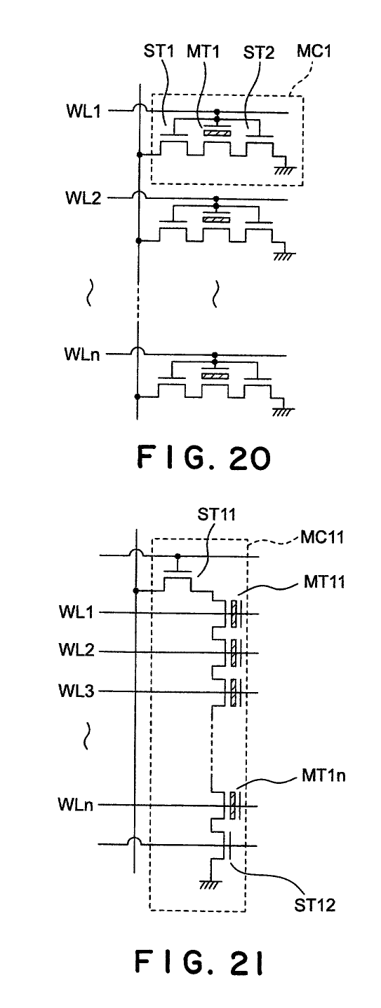

The arrangement of a MONOS nonvolatile semiconductor memory having a NAND cell array structure and a method of fabricating the same according to this embodiment will be explained by using FIGS. 1 to 13.

In this embodiment, oxide films having two different thicknesses, i.e., a thick HV (High Voltage) gate oxide film and a thin LV (Low Voltage) gate oxide film are formed as gate oxide films of peripheral transistors. In addition, an oxide film similar to the HV gate oxide film is formed as a gate oxide film of a selection transistor in a cell array.

As shown in FIG. 1, a pad oxide film 102 having a thickness of, e.g., 10 nm is formed on a p-type semiconductor substrate 101 by thermal oxidation or the like and patterned.

By using a resist film 103, phosphorus is ion-implanted as an n-type impurity into a surface portion of the semiconductor substrate 101 so that a desired depth and impurity profile are obtained, thereby forming a deep n-type well 104. In a surface portion of this n-type well 104, boron is ion-implanted as a p-type impurity so that a desired depth and impurity concentration are obtained, thereby forming a p-type well 105.

The resist film 103 is removed, and a resist film 107 is formed as shown in FIG. 2. An n-type impurity is ion-implanted to form an n-type well 106 around the p-type well 105.

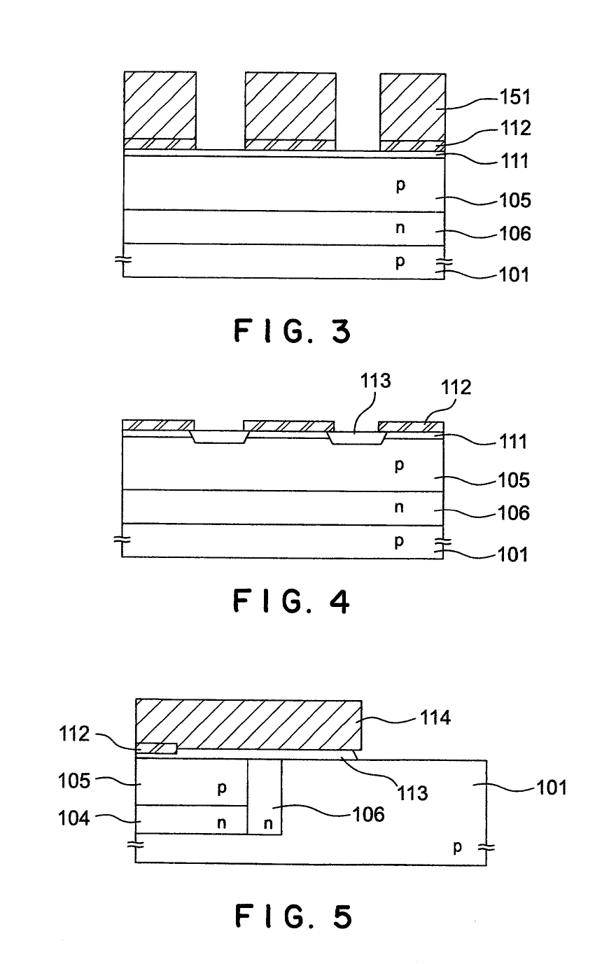

The pad oxide film 102 is removed as shown in FIG. 3. A silicon oxide film serving as a bottom oxide film 111 of a memory cell is formed to have a film thickness of 1 to 10 nm, e.g., 3 nm by thermal oxidation. In addition, a charge storage layer 112 which is, e.g., an SiN film, tantalum oxide film, strontium titanate film, or barium strontium titanate film is deposited to have a film thickness of 0.5 to 0.7 nm. When an SiN film is used, this SiN film can also be nitrided by N₂O or NH₃ to form an oxynitride film, in order to improve the reliability of the bottom oxide film.

The entire surface is coated with a resist, and a peripheral region and prospective selection transistor regions in a cell array are exposed. The resist is then patterned by development so as to cover prospective cell portions, thereby forming a resist film 151. This resist film 151 is used as a mask to perform RIE (Reactive Ion Etching) for the charge storage layer 112, removing portions of this layer from the openings. By this processing, the charge storage layer 112 remains only in the prospective cell portions.

A section shown in FIG. 4 is the longitudinal section of an element in the cell array, in which portions where the resist film 113 is exposed are the prospective selection transistor regions. After the resist film 112 is removed, the bottom oxide film 111 is removed from the openings by wet etching. A first gate oxidation step is performed by thermal oxidation to oxidize the surface of the substrate 101, forming a first gate oxide film 113 having a film thickness of, e.g., 5 nm. In this oxidation, the substrate surface in the prospective cell portions where the charge storage layer 112 remains is not oxidized.

As shown in FIG. 5, a resist is formed by coating and so patterned as to be removed from a prospective LV gate oxide film region in the peripheral region, forming a resist film 114. This resist film 114 is used as a mask to perform wet etching, thereby removing the first gate oxide film 113 from the prospective LV transistor region.

After the resist film 114 is removed, wet etching is again performed on the entire wafer surface to remove the first gate oxide film 113 by 1 to 2 nm.

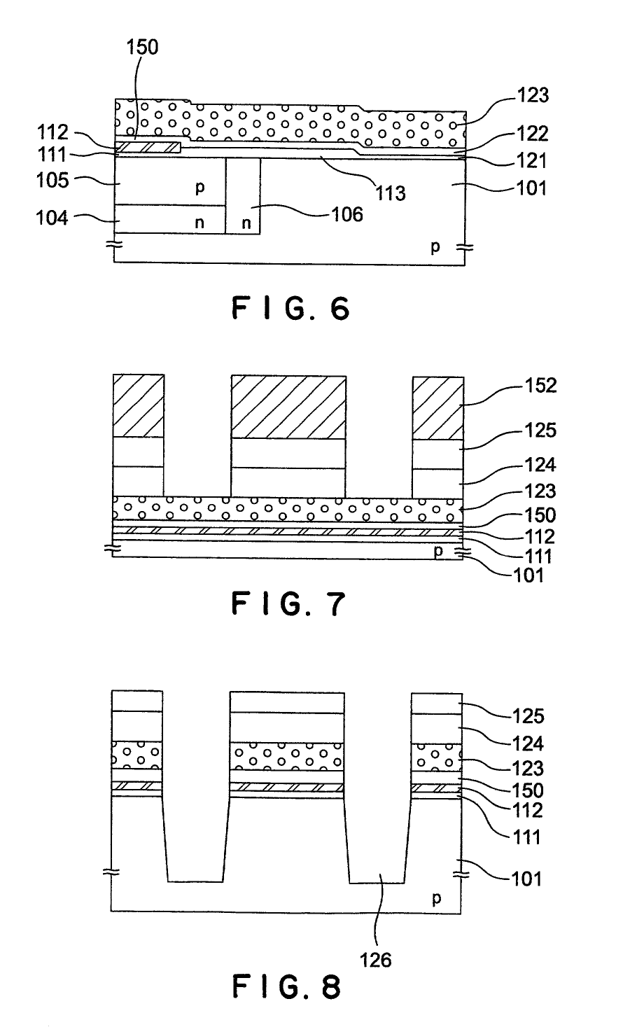

As shown in FIG. 6, a second gate oxidation step is performed by thermal oxidation to oxidize the substrate, forming a 2-nm thick second gate oxide film 121 on the prospective LV transistor region. An HTO (High Temperature Oxide) film 122 having a film thickness of, e.g., 5 nm is deposited on the entire surface, thereby forming a top oxide film 150 having a film thickness of 5 to 15 nm on the charge storage layer 112.

After that, to increase the density of the HTO film 122, a heat treatment such as additional annealing or oxidation is performed, or an oxynitride film is formed by nitriding using N₂O or NH₃. This can improve the reliability of the gate insulating film.

As shown in FIG. 7, a polysilicon film 123 serving as a gate electrode is deposited. In the resultant structure, a gate oxide film of an HV transistor in the peripheral region and a gate oxide film of a selection transistor in the memory cell region are stacked oxide films including a silicon oxide film in which the first and second gate oxide films 113 and 121 are stacked, and the HTO film 122.

On the other hand, a gate oxide film of an LV transistor in the peripheral region is a stacked oxide film including the second gate oxide film 121 and the HTO film 122.

By making the top oxide film thicker than the bottom oxide film, a phenomenon in which electric charge injected into the charge storage layer moves in programming/erasure is allowed to occur more easily on the bottom oxide film side.

Steps of forming active regions will be explained below by using FIGS. 7 to 13 showing the formation of element isolation in a memory cell portion.

As shown in FIG. 7, a 70-nm thick silicon nitride film 124 is deposited on the polysilicon film 123 so as to server as a mask material during etching for forming trenches in the substrate surface. A 200-nm thick TEOS- or silane-based oxide film 125 is deposited on this silicon nitride film 124, and the surface of the oxide film 125 is coated with a resist. Development is so performed as to cover active regions, forming a resist film 152 except for element isolation regions.

This resist film 152 is used as a mask to remove the silicon oxide film 125 and the silicon nitride film 124, as mask materials, in this order by using RIE. The resist film 152 is then removed. Consequently, the pattern of active regions is transferred from the resist film 152 onto the silicon oxide film 125 and the silicon nitride film 124.

As shown in FIG. 8, the stacked film of the silicon oxide film 125 and the silicon nitride film 124 is used as a hard mask to etch the polysilicon film 123 as a gate, a gate oxide film in the memory cell region, a gate oxide film of an HV transistor in the peripheral region, a gate oxide film of an LV transistor, and the semiconductor substrate 101 to a depth of about 200 nm from the substrate surface by using RIE, thereby forming element isolation trenches 126. In this etching, the boundary region between a memory cell and a selection transistor is set at mid-point between them on the active region.

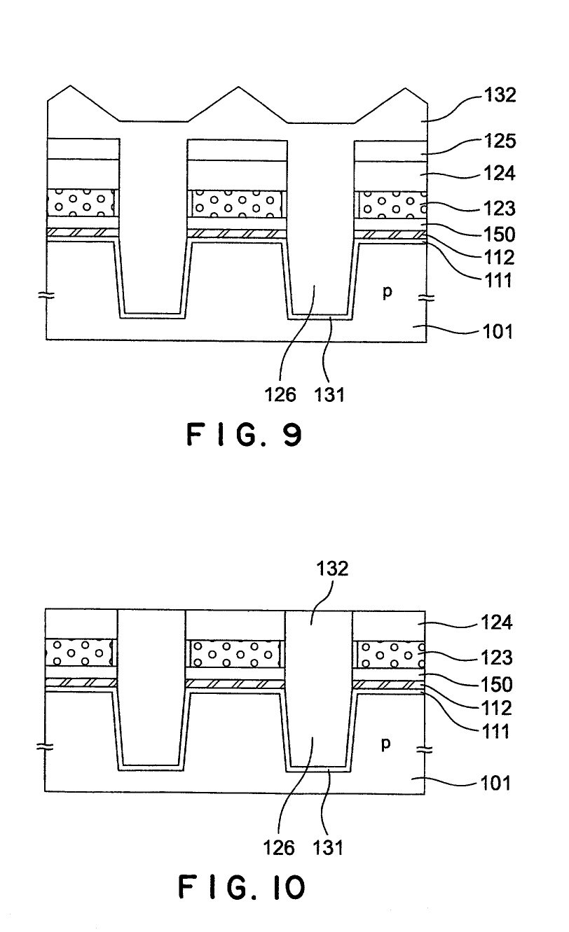

As shown in FIG. 9, the semiconductor substrate 101 is thermally oxidized to form a silicon oxide film 131 having a film thickness of, e.g., 3 to 6 nm. This silicon oxide film 131 is formed to protect the semiconductor substrate 101.

On the entire surface, a silicon oxide film 132 serving as a material for filling the trenches 126 is deposited. More specifically, a TEOS-based oxide film is deposited by CVD, or a silane-based oxide film is deposited by the HDP (High Density Plasma) method, so as to well cover from the trenches 126 in the semiconductor substrate 101 to the silicon oxide film 125. FIG. 9 shows the state in which the silicon oxide film 132 is buried by the HDP method.

Next, as shown in FIG. 10, the silicon oxide film 132 is planarized by CMP (Chemical Mechanical Polishing). In this polishing step, the silicon nitride film 124 functions as a polishing stopper.

After that, high-temperature annealing is performed at 900° C. or more to release stress generated when the trenches 126 are filled.

Subsequently, wet processing using buffered HF or the like is performed to remove, by lift-off, fine scratches on the surface of the silicon oxide film 126 buried in the trenches and foreign matter sticking to the surface during polishing.

As shown in FIG. 11, the silicon nitride film 124 is removed by wet etching using hot phosphoric acid. Furthermore, corners 126a of the silicon oxide film 132 buried in the trenches 126 are rounded by wet etching. A phosphorus-doped polysilicon film 133 serving as a gate line is deposited to have a film thickness of, e.g., 70 nm.

Annealing is then performed at, e.g., 850° C. for 30 min to diffuse the impurity from the polysilicon film 133 to the polysilicon film 123.

A tungsten silicide (WSi) film 141 having a film thickness of, e.g., 50 nm is deposited on the polysilicon film 133. A TEOS-based oxide film 142 serving as a mask material during gate electrode fabrication is deposited to have a film thickness of, e.g., 200 nm by CVD.

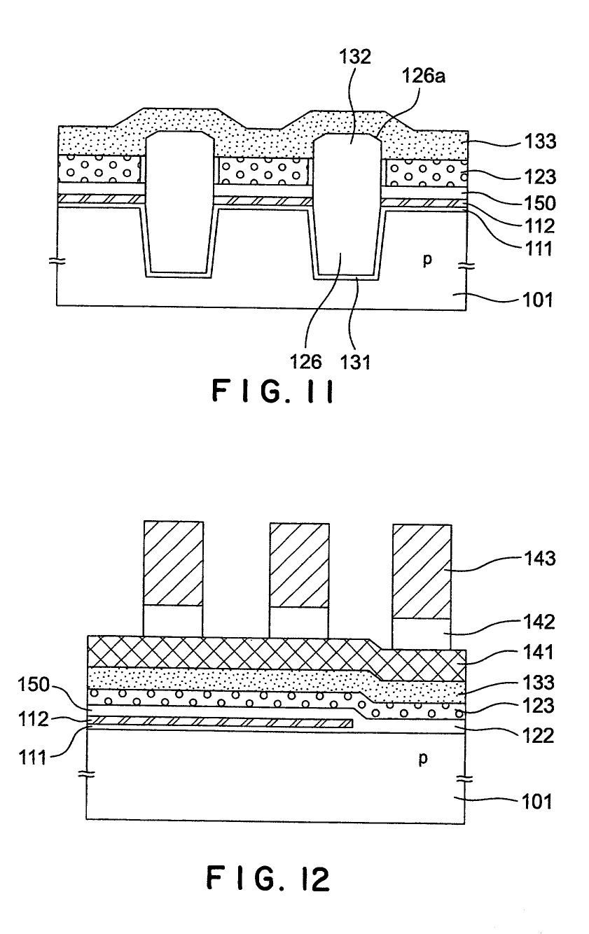

After that, as shown in FIG. 12, a resist is formed by coating and developed into the pattern of gate electrodes. A resist film 143 thus obtained is used to transfer the pattern onto the TEOS-based oxide film 142 as a mask material. FIG. 12 shows a gate section in the cell array. A region in which the charge storage layer 112 exists is a prospective memory cell region, and a region in which this charge storage layer 112 is absent is a prospective selection transistor region.

The resist film 143 is removed, and the TEOS-based oxide film 142 is used as a mask to etch the WSi film 141 and the polysilicon films 133 and 123. In addition, the gate insulating film is etched by RIE to remove the top oxide film 150 and the charge storage layer 112 of the cell. This etching is done such that the selection transistor gate insulating film remains.

After that, post-oxidation and impurity ion implantation are performed to form diffusion layers as a drain and source (not shown) in the memory cell and the peripheral transistor. In addition, a dielectric interlayer (not shown) made of BPSG or the like is formed. Contact holes are formed on the surfaces of the gate electrodes and diffusion layers through this dielectric interlayer, and a conductive material is buried to form contacts to the gate electrodes and diffusion layers. An interconnecting layer is formed on the dielectric interlayer by using a metal material or the like. A passivation layer is formed on the surface of this interconnecting layer to complete the fabrication process.

In the above embodiment, the charge storage layer 112 in a gate insulating film in a memory cell is formed only on a channel region of the cell, not on an element isolation region. Therefore, the phenomenon does not occur which is a problem for the charge retention characteristics, and in which electric charge moves from a charge storage layer on the channel of a cell transistor to a charge storage layer on the element isolation region. Accordingly, a good charge retention characteristics can be obtained.

Also, unlike a gate insulating film of a cell transistor, a gate insulating film of a selection transistor is formed only by silicon oxide films (the first gate oxide film 113, the second gate oxide film 121, and the HTO film 122) not including a charge storage layer. Therefore, the threshold voltage of the selection transistor does not vary, so a stable read operation is possible.

Furthermore, two gate oxide films different in film thickness are formed for peripheral transistors. That is, a thick gate oxide film (the first gate oxide film 113, the second gate oxide film 121, and the HTO film 122) is formed for an HV transistor requiring a high-breakdown-voltage gate oxide film, and a thin gate oxide film (the second gate oxide film 121 and the HTO film 122) is used for an LV transistor required to have not a high breakdown voltage but high drivability. This can improve the performance such as the operating speed.

The above embodiment is merely an example and hence does not limit the present invention. For example, in the above embodiment a WSi polycide structure in which a WSi film and a polysilicon film are stacked is used as a gate line. However, it is also possible to form a Ti or Co silicide for a diffusion layer and a gate line and a salicide for a cell and a peripheral transistor.

In the nonvolatile semiconductor memory and the method of fabricating same according to the embodiment as explained above, a charge storage layer necessary in a gate insulating film of a cell transistor is so formed as not to extend from a channel region of a cell to an element isolation region. Therefore, no electric charge moves from the charge storage layer on the channel onto the element isolation region. This improves the charge retention characteristics.

Also, unlike a gate insulating film of a cell transistor, a gate insulating film of a selection transistor is formed without including any charge storage layer. Since the threshold value of the selection transistor does not vary, read operation stabilizes.

Furthermore, of peripheral transistors, a thick gate oxide film is formed for a transistor requiring a high-breakdown-voltage gate oxide film, and a thin gate oxide film is formed for a transistor requiring not a high breakdown voltage but high drivability. This improves the performance such as the operating speed.

What is claimed is:

1. A nonvolatile semiconductor memory comprising:
a semiconductor substrate;
a first transistor formed on a surface of said semiconductor substrate and including a first gate insulating film and a first gate electrode; and
a second transistor formed on the surface of said semiconductor substrate and including a second gate insulating film and a second gate electrode,
wherein said first gate insulating film includes a charge storage layer and said second gate insulating film does not include a charge storage layer, and
said first and second transistors are isolated by a trench and said charge storage layer in said first transistor does not exist in an element isolation region and exists only below said first gate electrode in an element region.

2. A memory according to claim 1, wherein
said first gate insulating film comprises a 1- to 10-nm thick bottom silicon oxide film, a 0.5- to 7-nm thick silicon nitride film as said charge storage layer, and a 5- to 15-nm thick top silicon oxide film, and
the film thickness of said bottom silicon oxide film is smaller than that of said top silicon oxide film.

3. A memory according to claim 1, wherein
said first gate insulating film comprises a 1- to 10-nm thick bottom silicon oxide film, a tantalum oxide film as said charge storage layer, and a 5- to 15-nm thick top silicon oxide film, and
the film thickness of said bottom silicon oxide film is smaller than that of said top silicon oxide film.

4. A memory according to claim 1, wherein
said first gate insulating film comprises a 1- to 10-nm thick bottom silicon film, a film selected from the group consisting of a strontium titanate film and a barium strontium titanate film as said charge storage layer, and a 5- to 15-nm thick top silicon oxide film, and
the film thickness of said bottom silicon oxide film is smaller than that of said top silicon oxide film.

5. A memory according to claim 1, wherein
said nonvolatile semiconductor memory has a cell array which comprises said first transistor as a cell transistor and said second transistor as a selection transistor, and
said second gate insulating film in said second transistor has a 5- to 15-nm thick silicon oxide film.

6. A memory according to claim 1, wherein
said nonvolatile semiconductor memory comprises peripheral transistors in a peripheral region of said cell array,
said peripheral transistors include:
a first peripheral transistor formed on the surface of said semiconductor substrate and including a third gate insulting film and a third gate electrode; and
a second peripheral transistor formed on the surface of said semiconductor substrate and including a fourth gate insulating film and a fourth gate electrode, and
said third and fourth gate insulating films have different film thicknesses.

7. A method of fabricating a nonvolatile semiconductor memory having a cell array including a cell transistor and a selection transistor, comprising the steps of:
forming a first insulating film including a charge storage layer, on a surface of a semiconductor substrate, as a gate insulating film of the cell transistor;
forming a second insulating film not including a charge storage layer, on the surface of the semiconductor substrate, as a gate insulating film of the selection transistor; and
performing element isolation by forming a trench between an element region in which the cell transistor is to be formed and an element region in which the selection transistor is to be formed,
wherein the charge storage layer in the cell transistor does not exist in an element isolation region and exists only below said first gate electrode in the element region.

8. A method according to claim 7, wherein the first gate insulating film is formed by stacking a 1- to 10-nm bottom silicon oxide film, a 0.5- to 7-nm thick silicon nitride film as the charge storage layer, and a top silicon oxide film whose film thickness is 5 to 15 nm and not less than that of the bottom silicon oxide film.

9. A method according to claim 7, wherein the first gate insulating film is formed by stacking a 1- to 10-nm bottom silicon oxide film, a tantalum oxide film as the charge storage layer, and a top silicon oxide film whose film thickness is 5 to 15 nm and not less than that of the bottom silicon oxide film.

10. A method according to claim 7, wherein the first gate insulating film comprises a 1- to 10-nm thick bottom silicon film, a film selected from the group consisting of a strontium titanate film and a barium strontium titanate oxide film as the charge storage layer, and a top silicon oxide film whose film thickness is 5 to 15 nm and not less than that of the bottom silicon film.

11. A method according to claim 7, wherein the first and second gate insulating films include an HTO film as the topmost gate insulating layer.

12. A method of fabricating a nonvolatile semiconductor memory having a cell array including a cell transistor and a selection transistor, and a peripheral circuit including a peripheral transistor, comprising the steps of:
forming a first gate insulating film including a charge storage layer, on a surface of a semiconductor substrate, as a gate insulating film of the cell transistor;
forming a second gate insulating film not including a charge storage layer, on the surface of the semiconductor substrate, as a gate insulating film of the selection transistor;
forming a third gate insulating film not including a charge storage layer, on the surface of the semiconductor substrate, as a gate insulating film of the peripheral transistor; and
performing element isolation by forming trenches between an element region in which the cell transistor is to be formed, an element region in which the selection transistor is to be formed, and an element region in which the peripheral transistor is to be formed,
wherein the step of forming the second gate insulating film and the step of forming the third gate insulating film are simultaneously performed, and the charge storage layer in the cell transistor does not exist in an element isolation region and exists only below said first gate electrode in the element region.

13. A method according to claim 12, wherein the first gate insulating film is formed by stacking a 1- to 10-nm bottom silicon oxide film, a 0.5- to 7-nm thick silicon nitride film as the charge storage layer, and a top silicon oxide film whose film thickness is 5 to 15 nm and not less than that of the bottom silicon oxide film.

14. A method according to claim 12, wherein the first gate insulating film is formed by stacking a 1- to 10-nm bottom silicon oxide film, a tantalum oxide film as the charge storage layer, and a top silicon oxide film whose film thickness is 5 to 15 nm and not less than that of the bottom silicon oxide film.

15. A method according to claim 12, wherein the first gate insulating film comprises a 1- to 10-nm thick bottom silicon oxide film, a film selected from the group consisting of a strontium titanate film and a barium strontium titanate oxide film as the charge storage layer, and a top silicon oxide film whose film thickness is 5 to 15 nm and not less than that of the bottom silicon oxide film.

16. A method according to claim 12, wherein the first and second gate insulating films include an HTO film as the topmost gate insulating layer.

17. A method of fabricating a nonvolatile semiconductor memory having a cell array including a cell transistor and a selection transistor, and a peripheral circuit including first and second peripheral transistors, comprising the steps of:
forming a first gate insulating film including a charge storage layer, on a surface of a semiconductor substrate, as a gate insulating film of the cell transistor;
forming a second gate insulating film not including a charge storage layer, on the surface of the semiconductor substrate, as a gate insulating film of the selection transistor;
forming a third gate insulating film not including a charge storage layer, on the surface of the semiconductor substrate, as a gate insulating film of the first peripheral transistor;
forming a fourth gate insulating film not including a charge storage layer and thinner than the third gate insulating film, on the surface of the semiconductor substrate, as a gate insulating film of the second peripheral transistor; and
performing element isolation by forming trenches between an element region in which the cell transistor is to be formed, an element region in which the selection transistor is to be formed, and an element region in which the first and second peripheral transistors are to be formed,
wherein the step of forming the second gate insulating film and the step of forming the third gate insulating film are simultaneously performed, and the charge storage layer in the cell transistor does not exist in an element isolation region and exists only below said first gate electrode in the element region.

18. A method according to claim 17, wherein the first gate insulating film is formed by stacking a 1- to 10-nm bottom silicon oxide film, a 0.5- to 7-nm thick silicon nitride film as the charge storage layer, and a top silicon oxide film whose film thickness is 5 to 15 nm and not less than that of the bottom silicon oxide film.

19. A method according to claim 17, wherein the first gate insulating film is formed by stacking a 1- to 10-nm bottom silicon oxide film, a tantalum oxide film as the charge storage layer, and a top silicon oxide film whose film thickness is 5 to 15 nm and not less than that of the bottom silicon oxide film.

20. A method according to claim 17, wherein the first gate insulating film comprises a 1- to 10-nm thick bottom silicon oxide film, a film selected from the group consisting of a strontium titanate oxide film and a barium strontium titanate oxide film as the charge storage layer, and a top silicon oxide film whose film thickness is 5 to 15 nm and not less than that of the bottom silicon oxide film.

21. A method according to claim 17, wherein the first and second gate insulating films include an HTO film as the topmost gate insulating layer.
